(19) United States
(12) Patent Application Publication
(10) Pub. No.: US 2025/0204227 A1
(43) Pub. Date: Jun. 19, 2025

(54) DISPLAY APPARATUS

(71) Applicant: LG Display Co., Ltd., Seoul (KR)

(72) Inventors: SeoHyun NAM, Paju-si (KR); SeHong PARK, Paju-si (KR); InGoo LEE, Paju-si (KR)

(73) Assignee: LG Display Co., Ltd., Seoul (KR)

(21) Appl. No.: 18/920,668

(22) Filed: Oct. 18, 2024

(30) Foreign Application Priority Data
Dec. 19, 2023 (KR) 10-2023-0186078

(51) Int. Cl. H10K 59/80; H10K 59/123; H10K 59/35

(52) U.S. Cl. CPC H10K 59/879; H10K 59/123; H10K 59/351; H10K 59/8791

(57) ABSTRACT

A display apparatus for improving a light extraction efficiency of light emitted from a light emitting layer is provided. The display apparatus includes a plurality of pixels having a plurality of subpixels on a substrate, a pattern portion disposed on the substrate to be concave in a non-light emission area between the plurality of sub-pixels, and a reflective portion disposed to be inclined on the pattern portion. Each of the plurality of sub-pixels includes a plurality of concave portions disposed in a light emission area adjacent to the non-light emission area, and a pixel electrode disposed on the plurality of concave portions. A separation distance between the plurality of concave portions and the reflective portion is longer than a separation distance between the pixel electrode and the reflective portion.

### CROSS-REFERENCE TO RELATED APPLICATIONS

This application claims priority to Korean Patent Application No. 10-2023-0186078 filed in the Republic of Korea on Dec. 19, 2023, the entire contents of which is hereby expressly incorporated by reference into the present application.

### BACKGROUND

### Field

The present disclosure relates to a display apparatus for displaying images with improved light extraction efficiency.

### Discussion of the Related Art

Since an organic light emitting display apparatus has a high response speed and low power consumption and self-emits light without requiring a separate light source unlike a liquid crystal display apparatus, there is no issue in a viewing angle and thus the organic light emitting display apparatus has received attention as a next-generation flat panel display apparatus.

Such a display apparatus displays an image through the light emission of a light emitting element layer that includes a light emitting layer interposed between two electrodes.

Meanwhile, light extraction efficiency of the display apparatus may be reduced in some situations as some of the light emitted from the light emitting element layer may not be emitted to the outside due to the total reflection on the interface between multiple layers inside the display panel.

### SUMMARY OF THE DISCLOSURE

An aspect of the present disclosure is directed to providing a display apparatus in which the efficiency of light extraction from the light emitting layer can improve.

An aspect of the present disclosure is directed to providing a display apparatus which can reduce the overall power consumption by light extraction from the non-light emission area.

An aspect of the present disclosure is directed to providing a display which can maximize light extraction efficiency by a plurality of concave portions included in each of a plurality of sub-pixels.

The problems and limitations to be solved or addressed by embodiments of the present disclosure are not limited to those mentioned above, and other problems not mentioned above will be apparent to those skilled in the art to which the technical ideas of the present disclosure belong from the following descriptions.

A display apparatus according to as aspect of the present disclosure comprises a substrate including a plurality of pixels having a plurality of sub-pixels; a pattern portion disposed on the substrate to be concave in a non-light emission area between the plurality of sub-pixels; and a reflective portion disposed to be inclined on the pattern portion, wherein each of the plurality of sub-pixels includes: a plurality of concave portions disposed in an light emission area adjacent to the non-light emission area; and a pixel electrode disposed on the plurality of concave portions, and wherein a separation distance between the plurality of concave portions and the reflective portion is longer than a separation distance between the pixel electrode and the reflective portion.

The technical benefits of the present disclosure are not limited to the above-mentioned benefits, and other benefits, which are not mentioned above, can be clearly understood by those skilled in the art from the following descriptions.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to an embodiment of the present disclosure.

FIG. 2 is a schematic plan view of one pixel illustrated in FIG. 1.

FIG. 3 is a schematic cross-sectional view taken along a line I-I′ illustrated in FIG. 2.

FIG. 4 is a schematic cross-sectional view taken along a line II-II′ illustrated in FIG. 2.

FIG. 5 is a schematic enlarged plan view of portion A shown in FIG. 2.

FIG. 6 is a schematic enlarged cross-sectional view of portion B shown in FIG. 3.

FIG. 7 is a schematic enlarged cross-sectional view of the portion C shown in FIG. 3.

FIG. 8 is a schematic cross-sectional view showing light refraction in one concave portion shown in FIG. 7.

FIG. 9 is a graph illustrating an example of light intensity as a function of an angle of light incident on a concave portion of a display apparatus according to one embodiment of the present disclosure.

FIG. 10 is a graph illustrating an example of a ratio of refracted light intensity as a function of an aspect ratio of a concave portion of a display apparatus according to one embodiment of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part can be added unless ‘only˜’ is used. The terms of a singular form can include plural forms unless referred to the contrary.

In construing an element, the element is construed as including an error range although there is no explicit description. In describing a position relationship, for example, when a position relation between two parts is described as ‘on’, ‘over’, ‘under’, and ‘next’, one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms and may not define order or sequence. These terms are only used to distinguish one element from another. For example, a first element could be termed a second element, and, similarly, a second element could be termed a first element, without departing from the scope of the present disclosure.

Further, “X-axis direction”, “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, the embodiments of the present disclosure will be described in detail with reference to the accompanying drawings. All the components of each display apparatus according to all embodiments of the present disclosure are operatively coupled and configured.

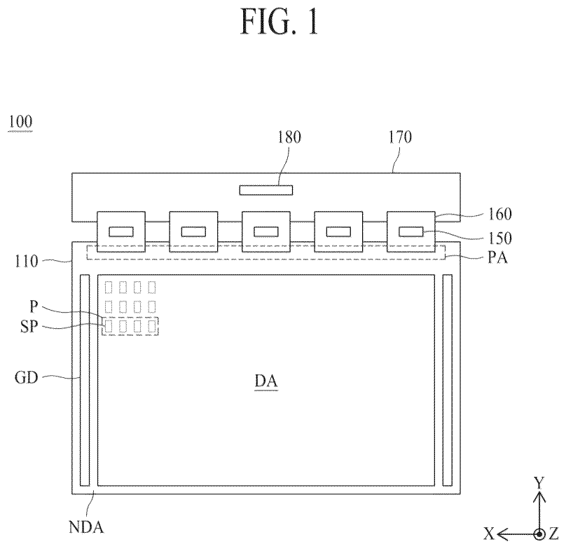

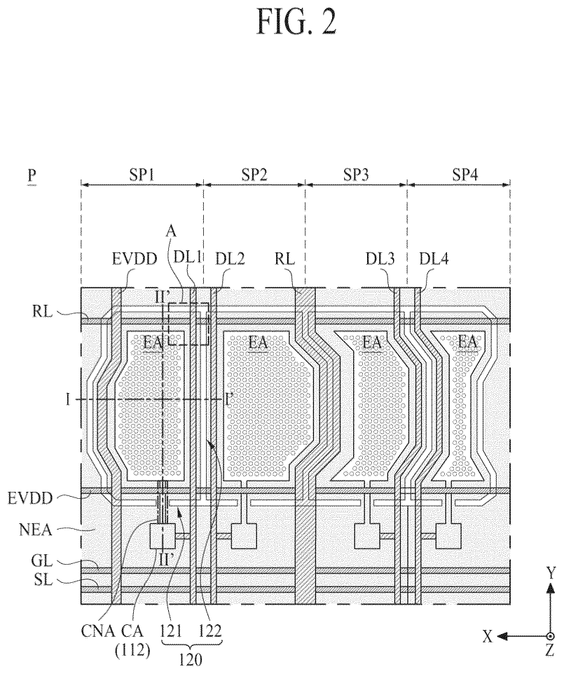

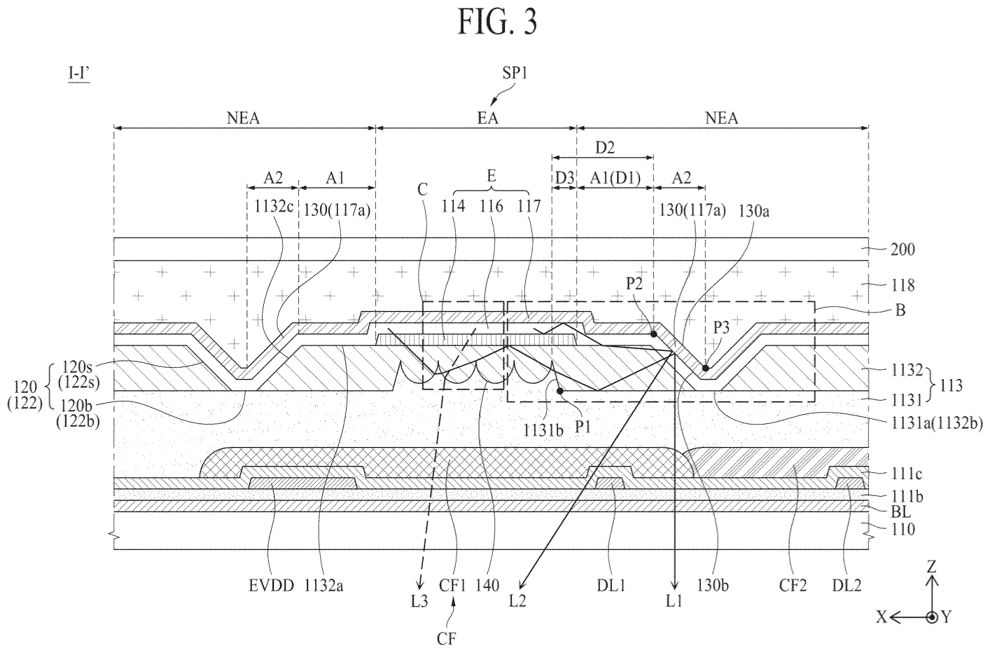

FIG. 1 is a schematic plan view of a display apparatus according to an embodiment of the present disclosure, FIG. 2 is a schematic plan view of an example of a pixel illustrated in FIG. 1, and FIG. 3 is a schematic cross-sectional view taken along a line I-I′ illustrated in FIG. 2.

Referring to FIGS. 1 to 3, a display apparatus 100 according to one embodiment of the present disclosure can include a substrate 110 having a plurality of pixels P having a plurality of subpixels SP, a pattern portion 120 disposed on the substrate 110 and formed to be concave in non-light emission area NEA between the plurality of subpixels SP, and a reflective portion 130 disposed to be inclined on the pattern portion 120.

Each of the plurality of subpixels SP can include a plurality of concave portions 140 disposed in a light emission area EA adjacent to the non-light emission area NEA, and a pixel electrode 114 disposed on the plurality of concave portions 140. Here, the distance by which the plurality of concave portions 140 and the reflective portion 130 are spaced apart is longer than the distance by which the pixel electrodes 114 and the reflective portion 130 are spaced apart. For example, the plurality of concave portions 140 can be spaced further apart from the reflective portion 130 than an edge of the pixel electrodes 114.

In the display apparatus 100 according to one embodiment of the present disclosure, the plurality of concave portions 140 having a lens shape is spaced further apart from the reflective portion 130 disposed in the non-light emission area NEA than the edges of the pixel electrodes 114, thus light emitted from the light emission area EA and incident on one of the plurality of concave portions 140 can be refracted through the at least one concave portion to form an optical path to the reflective portion 130.

Accordingly, the display apparatus 100 according to one embodiment of the present disclosure can allow light refracted through the at least one concave portion 140 to be emitted in the frontal direction (e.g., Z-axis direction in FIG. 3) of the substrate 110 through the reflective portion 130 disposed inclined to the non-light emission area NEA, thereby improving light extraction efficiency.

The light extraction efficiency can refer to a light extraction efficiency via a frontal extracted light L1, an inclined extracted light L2 that is reflected by the reflective portion 130 and emitted in an inclined direction toward the light emission area EA, and a direct light L3 that is not reflected by the reflective portion 130 and is emitted to a lower surface of the substrate 110 via the concave portion 140, as shown in FIG. 3. The frontal extracted light L1 according to one example can be light that is emitted in a direction perpendicular to the upper surface (or lower surface) of the substrate 110.

On the other hand, as shown in FIG. 3, the display apparatus 100 according to one embodiment of the present disclosure can have light extraction even in the non-light emission area NEA through the plurality of concave portions 140 and the reflective portions 130, thus the same luminous efficiency can be achieved with low power compared to a display apparatus without the reflective portions, or the luminous efficiency can be further improved, resulting in lower overall power consumption.

Hereinafter, reference to FIGS. 1 to 3, the display apparatus 100 according to an embodiment of the present disclosure will be described in more detail.

Each of the plurality of subpixels SP according to one example can include the light emission area EA, the non-light emission area NEA adjacent to the light emission area EA, the plurality of concave portions 140 disposed overlapping the light emission area EA, and the pixel electrode 114 disposed on the plurality of concave portions 140.

The light emission area EA is an area from which light is emitted, and can be included in the display area DA. The non-light emission area NEA is an area from which light is not emitted, and can be an area adjacent to the light emission area EA. The non-light emission area NEA can be provided to surround the light emission area EA. The non-light emission area NEA can be referred to as a term of a peripheral area. The reflective portion 130 can be disposed adjacent to (or facing) the plurality of concave portions 140 in the non-light emission area NEA and spaced apart from the light emission area EA.

Therefore, in the display apparatus 100 according to one embodiment of the present disclosure, since the reflective portion 130 disposed in the non-light emission area NEA can reflect light, which is directed toward the subpixel adjacent thereto among light emitted from the light emission area EA, toward the subpixel SP for emitting light, light efficiency (or light extraction efficiency) of the subpixel SP for emitting light can be improved.

The non-light emission area NEA according to one example can include a first area A1 adjacent to the light emission area EA and a second area A2 adjacent to the first area A1 and spaced apart from the light emission area EA. The first area A1 and the second area A2 according to one example can be a bank-less area in which a bank is not disposed.

The pattern portion 120 according to one example can be formed to be concave the non-light emission area NEA. For example, the pattern portion 120 can be formed to be concave in an overcoat layer 113 (shown in FIG. 3) on the substrate 110. The pattern portion 120 can be disposed to be spaced apart from the light emission area EA. The overcoat layer 113, according to one example, can include a first layer 1131 and a second layer 1132 disposed on the first layer 1131. The pattern portion 120 can be formed by being patterned and removed a portion of the second layer 1132 that the overcoat layer 113 includes. Accordingly, the pattern portion 120 can be expressed in terms of grooves, slits, recesses, trenches, overcoat layer slits, and overcoat layer trenches.

The pattern portion 120 according to one example can be provided to surround the light emission area EA in the form of a slit or a trench. For example, a width of the pattern portion 120 can be formed to be reduced in a direction from the reflective portion 130 toward the substrate 110 (or in the direction from the pixel electrode 114 toward the substrate 110). As shown in FIG. 3, the pattern portion 120 can include an inclined surface 120s formed in the second area A2, and a bottom surface 120b extending from the inclined surface 120s and arranged in parallel with the upper surface of the substrate 110. The inclined surface 120s can be an inclined surface of the second layer 1132. The bottom surface 120b can be a portion of an upper surface 1131a (or a flat surface 1131a) of the first layer 1131.

Meanwhile, as shown in FIG. 3, the pattern portion 120 can comprise, but is not necessarily limited to, the inclined surface 120s of the second layer 1132 and the bottom surface 120b of the first layer 1131. In another example, the pattern portion 120 can be formed only on the second layer 1132. In this case, the inclined surface of the pattern portion 120 can be an inclined surface of the second layer 1132, and the bottom surface of the pattern portion 120 can be a bottom surface of the second layer 1132.

The reflective portion 130 according to one example can be formed to be inclined (or concave) along a profile of the pattern portion 120 formed to be concave the non-light emission area NEA, thereby being formed to be concave the non-light emission area NEA. The reflective portion 130 can be made of a material capable of reflecting light, and can reflect light, which is emitted from the light emission area EA and directed toward the adjacent subpixel SP, toward the light emission area EA for emitting light. As shown in FIG. 3, since the reflective portion 130 is disposed to be inclined on the pattern portion 120 while surrounding the light emission area EA, the reflective portion 130 can be expressed as terms such as a side reflective portion or an inclined reflective portion.

On the other hand, the display apparatus 100 according to one embodiment of the present disclosure can be implemented as a bottom emission type in which the light emitted from the light emission area EA is emitted through the lower surface of the substrate 110. Thus, in the display apparatus 100 according to an exemplary embodiment of the present disclosure, the extracted light emitted through the lower surface of the substrate 110 can be a combination of the direct light L3 emitted from the light emission area EA and directly emitted to the lower surface of the substrate 110 through at least one of the plurality of concave portions 140, and the reflected light emitted from the light emission area EA, directed to an adjacent sub-pixel SP, reflected on the reflective portion 130 and emitted to the lower surface of the substrate 110. The frontal extracted light L1 and the inclined extracted light L2 described above can be included in the reflected light. Accordingly, the display apparatus 100 according to one embodiment of the present disclosure can have an improved light extraction efficiency compared to a display apparatus that does not include the reflective portion 130 disposed inclined to the non-light emission area NEA.

In the case of a general display apparatus without a reflective portion, to improve light extraction efficiency, a plurality of lenses (or a plurality of concave portions) are disposed to overlap up to an edge (or an end) of the light emission area, i.e., a pixel electrode. In contrast, the display apparatus 100 according to one embodiment of the present disclosure has a structural feature in which the distance D2 at which the plurality of concave portions 140 (or an outermost concave portion disposed at the outermost edge of the plurality of concave portions 140) are spaced apart from the reflective portion 130 is longer than the distance D1 at which the pixel electrode 114 (or the edge (or end) of the pixel electrode 114) is spaced apart from the reflective portion 130. For example, the outermost concave portion 140 of the plurality of concave portions 140 can be spaced apart from the edges of the pixel electrodes 114. For example, the outermost concave portion 140 can be disposed spaced further apart from the reflection portion 130 toward a center portion of the pixel electrode 114 than toward an edge of the pixel electrode 114.

The reason the display apparatus 100 according to one embodiment of the present disclosure has this structural feature is that at least one concave portion 140 of the plurality of concave portions 140 refracts light incident from the light emission area EA to form a light path toward the reflective portion 130, thereby enabling light to be extracted from the non-light emission area NEA as well, resulting in a more improved light extraction efficiency compared to a typical display apparatus without a reflective portion.

Further, as shown in FIG. 3, in the display apparatus 100 according to one embodiment of the present disclosure, the plurality of concave portions 140 (or the outermost disposed concave portion 140 of the plurality of concaves) are spaced apart from the reflective portion 130 by the distance D2, the pixel electrodes 114 (or the edges of the pixel electrodes 114) are spaced apart from the reflective portion 130 by the distance D1 and the distance D2 between the plurality of concave portions 140 and the reflective portion 130 is disposed to be longer than the distance D1 between the pixel electrodes 114 and the reflective portion 130, thus after light refracted by the outermost concave portion 140 (or the outermost disposed concave portion 140 of the plurality of concave portions 140) is totally reflected from the upper surface 1131a of the first layer 1131 (or the interface between the first layer 1131 and the second layer 1132), light refracted by the outermost concave portion 140 (or the outermost disposed concave portion 140 of the plurality of concave portions 140) can be reflected by the reflective portion 130 and emitted as the front extracted light L1. In other words, the display apparatus 100 according to one embodiment of the present disclosure can have improved light extraction efficiency through light refraction through the plurality of concave portions 140, total reflection from the upper surface 1131a of the first layer 1131 (or the interface between the first layer 1131 and the second layer 1132), and reflection by the reflective portion 130 disposed inclined in the non-light emission area NEA.

Accordingly, the display apparatus 100 according to one embodiment of the present disclosure is provided to have the shortest horizontal distance PHL between the reflective portion 130 (or an uppermost point of the lower surface 130b of the reflective portion 130 (i.e., P2)) and an edge of the upper surface 1131a of the first layer 1131 (the left end of the upper surface 1131a of the first layer 1131 adjacent to the right outermost concave portion 140 with reference to FIG. 3 (i.e., P1)) satisfy a relationship (Equation 1):

$$PHL = h * tan ( 2 a )$$

Here, as an example, h represents a thickness of the second layer 1132 disposed on the flat surface of the first layer 1131, and a represents an angle between the reflective portion 130 and the flat surface of the first layer 1131.

Thus, light refracted through at least one of the concave portion 140 can be provided to be reflected by the reflective portion 130, after being totally reflected by the upper surface 1131a of the first layer 1131 (or an interface of the first layer 1131 and the second layer 1132). This will be described in more detail later.

Further, the display apparatus 100 according to one embodiment of the present disclosure can be provided to optimally have an aspect ratio (or optimal aspect ratio) of each of the plurality of concave portions 140, thus light having a large light intensity among light incident on one of the plurality of concave portions 140 can be refracted toward the reflective portion 130. This is because the greater the light intensity incident on the reflective portion 130, the greater the amount of the frontal extracted light L1 can be increased, and thus the overall light extraction efficiency can be improved. Therefore, the inventor who invented the display apparatus 100 according to one embodiment of the present description simulated the intensity of refracted light arriving at the reflective portion 130 through the concave portion 140 having various aspect ratios, and thereby being derived an aspect ratio of the concave portion 140 such that refracted light having a value more than or equal to 90% with respect to the intensity of refracted light having a maximum value arrives at the reflective portion 130. This will be described by explaining the overall structure of the display apparatus 100, followed by a mathematical expression.

Referring to FIGS. 1 and 2, the display apparatus 100 according to one embodiment of the present disclosure can further include a display panel, a plurality of concave portions 140, a source drive integrated circuit (IC) 150, a flexible film 160, a circuit board 170, and a timing control portion 180, herein the display panel includes a gate driver GD, and the plurality of concave portions 140 overlaps the light emission area EA.

The display panel can include a substrate 110 and an opposite substrate 200 (shown in FIG. 3).

The substrate 110 can include a thin film transistor, and can be a transistor array substrate, a lower substrate, a base substrate, or a first substrate. The substrate 110 can be a transparent glass substrate or a transparent plastic substrate. The substrate 110 can include a display area DA and a non-display area NDA.

The display area DA is an area where an image is displayed, and can be a pixel array area, an active area, a pixel array unit, a display unit, or a screen. For example, the display area DA can be disposed at a central portion of the display panel. The display area DA can include a plurality of pixels P.

The opposite substrate 200 can encapsulate (or seal) the display area DA disposed on the substrate 110. For example, the opposite substrate 200 can be bonded to the substrate 110 via an adhesive member (or clear glue). The opposite substrate 200 can be an upper substrate, a second substrate, or an encapsulation substrate.

The gate driver GD supplies gate signals to the gate lines in accordance with the gate control signal input from the timing controller 190. The gate driver GD can be formed on one side of the light emission area EA or in the non-light emission area NEA outside both sides of the light emission area EA in a gate driver in panel (GIP) method, as shown in FIG. 1.

The non-display area NDA is an area on which an image is not displayed, and can be a peripheral area, a signal supply area, an inactive area or a bezel area. The non-display area NDA can be configured to be in the vicinity of the display area DA. For example, the non-display area NDA can be disposed to surround the display area DA.

A pad area PA can be disposed in the non-display area NDA. The pad area PA can supply a power source and/or a signal for outputting an image to the pixel P provided in the display area DA. Referring to FIG. 1, the pad area PA can be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. When the source drive IC 150 is manufactured as a driving chip, the source drive IC 150 can be packaged in the flexible film 160 in a chip on film (COF) method or a chip on plastic (COP) method.

Pads, such as data pads, can be formed in the non-display area NDA of the display panel. Lines connecting the pads with the source drive IC 150 and lines connecting the pads with lines of the circuit board 170 can be formed in the flexible film 160. The flexible film 160 can be attached onto the pads by using an anisotropic conducting film, whereby the pads can be connected with the lines of the flexible film 160.

The circuit board 170 can be attached to the flexible films 160. A plurality of circuits implemented as driving chips can be packaged in the circuit board 170. For example, the timing controller 180 can be packaged in the circuit board 170. The circuit board 170 can be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD, and supplies the source control signal to the source drive ICs 150.

Referring to FIG. 2, the substrate 110 according to an example can include the light emission area EA and the non-light emission area NEA.

The light emission area EA can mean an area from which light is emitted. A light emitting element layer E, which includes a pixel electrode 114, an organic light emitting layer 116 and a reflective electrode 117, can be disposed in the light emission area EA. When an electric field is formed between the pixel electrode 114 and the reflective electrode 117, the organic light emitting layer 116 in the light emission area EA can emit light.

On the other hand, the light emission area EA can have the same or similar shape as the shape of the pixel electrode 114. This is because light can be emitted from the organic light emitting layer 116 depending on the formation of the electric field between the pixel electrode 114 and the reflective electrode 117. Since the area in which light is emitted is the light emission area EA, the light emission area EA can be formed along the shape of the pixel electrode 114. The pattern portion 120 according to one example is provided to surround the light emission area EA, and consequently, the pattern portion 120 can be formed along the shape of the pixel electrode 114.

As shown in FIG. 3, a portion of the light emitted from the organic light emitting layer 116 can be wave-guided by being totally reflected by a difference in refractive index between the organic light emitting layer 116 and the reflective electrode 117 on the organic light emitting layer 116 and a difference in refractive index difference between the organic light emitting layer 116 and the pixel electrode 114 below the organic light emitting layer 116. The wave-guided light can form an optical path toward an adjacent subpixel along the interface of the organic light emitting layer 116. In the display apparatus according to one embodiment of the present disclosure, the reflective portion 130 can be disposed between the subpixels SP to reflect the light, which is directed toward the adjacent subpixel, toward the subpixel for emitting light. Therefore, the display apparatus 100 according to one embodiment of the present disclosure can improve light efficiency of the subpixel for emitting light by extracting the light, which is dissipated by the wave-guide, by the reflective portion 130. Further, in the display apparatus 100 according to one embodiment of the present disclosure, the reflective portion 130 disposed between the subpixels SP can prevent color mixture caused by the wave-guide from occurring.

For example, light can be extinction by a wave guide, and the display apparatus 100 according to one embodiment of the present disclosure can be capable of emitting light that can be extinction through the reflective portion 130 in the form of reflected light (or the inclined extracted light L2) toward the emitting sub-pixel SP, thereby improving light efficiency.

Furthermore, the display apparatus 100 according to one embodiment of the present disclosure can be capable of emitting light that can cause mixing through the reflective portion 130 in the form of reflected light (or the inclined extracted light L2) toward the emitting sub-pixel SP, so that light efficiency can be maximized.

As a result, the display apparatus 100 according to one embodiment of the present disclosure can have an improved overall light efficiency while preventing mixing with neighboring subpixels SP via the reflective portion 130.

Referring back to FIG. 2, the light emission area EA according to an example can include gate lines, data lines, pixel driving power lines, and a plurality of pixels P. Each of the plurality of pixels P can include a plurality of subpixels SP that can be defined by the gate lines and the data lines.

Meanwhile, at least four subpixels, which are provided to emit different colors and disposed to be adjacent to one another, among the plurality of subpixels SP can constitute one pixel P (or unit pixel). One pixel P can include, but is not limited to, a red subpixel, a green subpixel, a blue subpixel and a white subpixel. One pixel P can include three subpixels SP provided to emit light of different colors and disposed to be adjacent to one another. For example, one pixel P can include a red subpixel, a green subpixel and a blue subpixel.

Each of the plurality of subpixels SP includes a thin film transistor and a light emitting element layer E connected to the thin film transistor. Each of the plurality of subpixels can include a light emitting layer (or an organic light emitting layer) interposed between the pixel electrode and the reflective electrode.

The light emitting layer respectively disposed in the plurality of subpixels SP can individually emit light of different colors or emit white light in common. Since the light emitting layer of each of the plurality of subpixels SP commonly emit white light, each of the red subpixel, the green subpixel and the blue subpixel can include a color filter CF (or wavelength conversion member CF) for converting white light into light of its respective different color. In this case, the white subpixel may not include a color filter.

In the display apparatus 100 according to one embodiment of the present disclosure, an area provided with a red color filter can be a red subpixel or a first subpixel, an area provided with a green color filter can be a green subpixel or a second subpixel, an area provided with a blue color filter can be a blue subpixel or a third subpixel, and an area in which the color filter is not provided can be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels can emit light with a predetermined brightness in accordance with the predetermined current.

The plurality of subpixels SP according to one example can be disposed to be adjacent to each other in a first direction (e.g., X-axis direction). The first direction (X-axis direction) can be a horizontal direction based on FIG. 1. The horizontal direction can be a direction in which a gate line is disposed.

A second direction (e.g., Y-axis direction) is a direction crossing the first direction (X-axis direction), and can be a vertical direction based on FIG. 1. The vertical direction can be a direction in which a data line is disposed.

A third direction (e.g., Z-axis direction) is a direction crossing each of the first direction (X-axis direction) and the second direction (Y-axis direction), and can be a thickness direction of the display apparatus 100.

The plurality of subpixels SP can include a first subpixel SP1, a second subpixel SP2, a third subpixel SP3 and a fourth subpixel SP4 arranged adjacent to each other in the first direction (X-axis direction). For example, the first subpixel SP1 can be a red subpixel, the second subpixel SP2 can be a green subpixel, the third subpixel SP3 can be a blue subpixel and the fourth subpixel SP4 can be a white subpixel, but is not limited thereto. However, the arrangement order of the first subpixel SP1, the second subpixel SP2, the third subpixel SP3 and the fourth subpixel SP4 can be changed.

Each of the first to fourth subpixels SP1 to SP4 can include a light emission area EA and a circuit area. The light emission area EA can be disposed at one side (or an upper side) of a subpixel area, and the circuit area can be disposed at the other side (or a lower side) of the subpixel area. For example, the circuit area can be disposed at the lower side of the light emission area EA based on the second direction (Y-axis direction). The light emission areas EA of the first to fourth subpixels SP1 to SP4 can have same sizes (or areas) as each other, or different sizes (or areas) as each other.

The first to fourth subpixels SP1 to SP4 can be disposed to be adjacent to one another along the first direction (X-axis direction). For example, two data lines extended along the second direction (Y-axis direction) can be disposed in parallel with each other between the first subpixel SP1 and the second subpixel SP2 and between the third subpixel SP3 and the fourth subpixel SP4. A pixel power line extended along the first direction (X-axis direction) can be disposed between the light emission area EA and the circuit area of each of the first to fourth subpixels SP1 to SP4. The gate line and a sensing line can be disposed below the circuit area. The pixel power line EVDD (shown in FIG. 2) extended along the second direction (Y-axis direction) can be disposed at one side of the first subpixel SP1 or the fourth subpixel SP4. A reference line extended along the second direction (Y-axis direction) can be disposed between the second subpixel SP2 and the third subpixel SP3. The reference line RL can be used as a sensing line for sensing a change of characteristics of a driving thin film transistor and/or a change of characteristics of the light emitting element layer, which is disposed in the circuit area, from the outside in a sensing driving mode of the pixel P. At least a portion of the reference line RL according to one example can overlap the pattern portion 120.

In one example, the data lines are for supplying data signals to each of the plurality of the subpixels SP to drive each of the plurality of subpixels SP. For example, the data lines can include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

In the display apparatus 100 according to one embodiment of the present disclosure, the data lines, for example, the first data line DL1 can be disposed not to overlap the light emission area EA and the reflective portion 130 (or a reflective portion 117a), herein the reflective portion 130 is disposed on the pattern portion 120. For example, as shown in FIG. 3, the first data line DL1 can be disposed to overlap the first area A1. Accordingly, the display apparatus 100 according to one embodiment of the present disclosure can be prevented from reducing light extraction efficiency because the first data line DL1 does not obscure (or interfere with) the light reflected by the reflective portion 130 (or the reflective portion 117a). The second data line DL2, the third data line DL3, and the fourth data line DL4 can be disposed in the first area A1 of the corresponding sub-pixel, such as the first data line DL1 such that the light emission area EA and the reflective portion 117a of the corresponding sub-pixel, respectively, are not overlapped in the third direction (Z-axis direction). Thus, in the display apparatus 100 according to one embodiment of the present disclosure, the data lines DL1, DL2, DL3, DL4 can have structural features that do not overlap with the pattern portion 120.

In the display apparatus 100 according to one embodiment of the present disclosure, each of the data lines DL1, DL2, DL3, DL4 can be extended in a second direction (Y-axis direction) intersecting the first direction (X-axis direction) between the plurality of subpixels SP disposed in the first direction (X-axis direction). The pattern portion 120 according to one example can partially overlap with the data lines DL1, DL2, DL3, DL4 in the first direction (X-axis direction) and the second direction (Y-axis direction), as shown in FIG. 2. As shown in FIG. 2, the pattern portion 120 is disposed to surround most of the light emission area EA.

Meanwhile, since the pixel power wiring EVDD and the reference line RL each have a wide width compared to the data line, they can be arranged overlapping not only the first area A1 but also up to the second area A2. Therefore, in the display apparatus 100 according to one embodiment of the present disclosure, each of the pixel power wiring EVDD and the reference line RL can have a structure that partially overlaps the pattern portion 120.

In the display apparatus 100 according to one embodiment of the present disclosure, each of the plurality of subpixels SP can include the plurality of concave portions 140. The plurality of concave portions 140 can be formed on the overcoat layer 113 (shown in FIG. 3) to overlap with the light emission area EA of the sub-pixel. By forming the plurality of concave portions 140 on the overcoat layer 113 of the light emission area EA so as to have a curved (or uneven) shape, the plurality of concave portions 140 changes the progression path of the light emitted from the light-emitting element layer E to increase light extraction efficiency. For example, the plurality of concave portions 140 can refract light emitted from the organic light emitting layer 116 toward the reflective portion 130 (or the reflective portion 117a) on the pattern portion 120. For example, the plurality of concave portions 140 can be a non-planar portion, an irregular pattern portion, a microlens portion, or a light scattering pattern portion.

The plurality of concave portions 140 can be formed to be concave inside the overcoat layer 113. For example, the plurality of concave portions 140 can be provided by the upper surface of the first layer 1131 included in in the overcoat layer 113 being formed to have a plurality of concaves. Therefore, the first layer 1131 can include a plurality of concave portions 140. The first layer 1131 can be disposed between the substrate 110 and the light emitting element layer E in the third direction (Z-axis direction). The concave portions 140 can be disposed adjacent to the pattern portion 120 in the first direction (X-axis direction).

A second layer 1132 of the overcoat layer 113 can be disposed between the first layer 1131 and a light emitting element layer E (or a pixel electrode 114 shown in FIG. 3). The second layer 1132 according to one example can be formed to be wider than the pixel electrode 114 in a first direction (X-axis direction). Thus, a portion of the second layer 1132 can overlap with the light emission area EA, and the remainder can partially overlap with the first area A1 and the second area A2 of the non-light emission area NEA. For example, as shown in FIG. 3, the second layer 1132 can extend from the light emission area EA to a portion of the second area A2 and partially overlap on the second area A2. As the upper surface 1132a of the second layer 1132 is provided with a flat surface, the pixel electrode 114 disposed on the upper surface 1132a of the second layer 1132 can also be provided with a flat surface. The organic light emitting layer 116 can be disposed on the second layer 1132.

Meanwhile, a refractive index of the second layer 1132 can be greater than that of the first layer 1131. Therefore, as shown in FIG. 3, a path of light emitted from a light emitting layer 116 and directed toward the substrate 110 can be changed toward the reflective portion 130 (or the reflective portion 117a) due to a difference in refractive indexes between the second layer 1132 and the first layer 1131 of the plurality of concave portions 140. Thus, light that is directed to the reflective portion 130 by the plurality of concave portions 140 can be reflected by the reflective portion 130 and directed toward the light emission area EA of the subpixel SP or can be directed in the form of the frontal extracted light L1 from the non-light emission area NEA. Hereinafter, the light reflected in the reflective portion 130 and emitted toward the substrate 110 will be defined as the reflective light.

As shown in FIG. 3, reflected light can include a first reflected light L1 (or the frontal extracted light L1) (or substrate mode extracted light L1) that is emitted from the organic light emitting layer 116, refracted by at least one concave portion 140 of the plurality of concave portions 140, and then totally reflected from the interface between the flat surface 1131a (or the upper surface 1131a) of the first layer 1131 and the second layer 1132, and reflected from the reflective portion 130 and directed to the substrate 110. Further, the reflected light can include a second reflected light L2 (or inclined extracted light L2) (or WG mode extracted light L2) that is emitted from the organic light emitting layer 116, refracted by at least one concave portion 140 of the plurality of concave portions 140, and then totally reflected from the interface between the flat surface 1131a (or the upper surface 1131a) of the first layer 1131 and the second layer 1132, and reflected from the reflective portion 130 and directed to the substrate 110 after being waveguided through being totally reflected between the pixel electrode 114 and the reflective electrode 117 (and/or being totally reflected between the reflective electrode 117 and the second layer 1132). Here, the flat (upper) surface 1131a of the first layer 1131 can be a flat surface that is arranged in parallel with the substrate 110 (or an upper surface of the substrate 110). As shown in FIG. 3, the flat (upper) surface 1131a of the first layer 1131 can be disposed closer to the substrate 110 than the plurality of concave portions 140.

As shown in FIG. 3, the first reflected light L1 according to an example can be emitted from the non-light emission area NEA, and the second reflected light L2 can be emitted from the light emission area EA. For example, the first reflected light L1 can be emitted from the non-light emission area NEA or the surrounding area. This is because the reflective portion 130 (or the reflective portion 117a) disposed on the pattern portion 120 is inclined to the non-light emission area NEA. However, without being limited thereto, the second reflected light L2 can be emitted from the non-light emission area NEA depending on the angle at which it is incident on the reflective portion 130.

On the other hand, the display apparatus 100 according to one embodiment of the present disclosure can further include light that is not reflected by the reflective portion 130 and is directed to the substrate 110 through the plurality of concave portions 140. For example, as shown by the dashed lines in FIG. 3, light emitted from the organic light emitting layer 116 and incident on one of the plurality of concave portions 140 can further include direct light L3 that is refracted at the periphery forming the concave portion 140 (or at the interface between the first layer 1131 and the second layer 1132 forming the concave portion 140) and is emitted onto the substrate 110. Thus, the display apparatus 100 according to one embodiment of the present disclosure can improve overall light extraction efficiency through the plurality of concave portions 140 and the reflective portions 130.

In the display apparatus 100 according to one embodiment of the present disclosure, since the pattern portion 120 is disposed to surround the light emission area EA, at least a portion of the reflective portion 130 on the pattern portion 120 can be disposed to surround the light emission area EA. Therefore, the reflective light can be emitted toward the substrate 110 from the position spaced apart from the light emission area EA or from the light emission area EA while surrounding at least a portion of the light emission area EA. Therefore, in the display apparatus 100 according to one embodiment of the present disclosure, since light dissipated by waveguide (or optical waveguide) and/or light dissipated by the interface total reflection can be emitted from the non-light emission area NEA in the form of reflective light through the reflective portion 130 surrounding at least a portion of the light emission area EA, light extraction efficiency can be improved and the overall light emission efficiency can be increased.

Hereinafter, a structure of each of the plurality of subpixels SP will be described in detail.

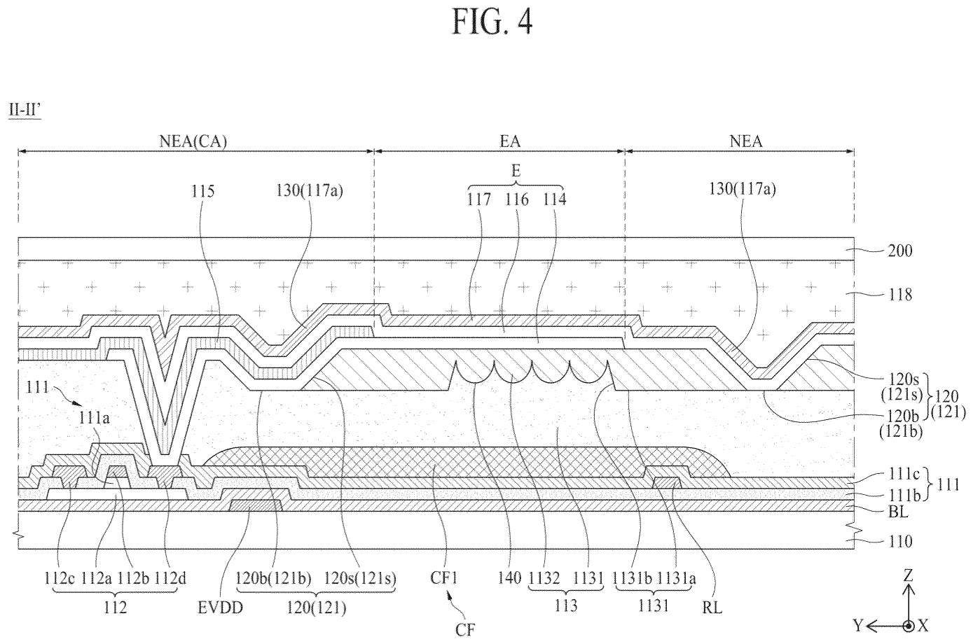

FIG. 4 is a schematic cross-sectional view taken along a line II-II′ illustrated in FIG. 2

Referring to FIG. 4, the display apparatus 100 according to one embodiment of the present disclosure can further include a buffer layer BL, a circuit element layer 111, a thin film transistor 112, a pixel electrode 114, a bank 115, the organic light emitting layer 116, a reflective electrode 117, an encapsulation layer 118 and a color filter CF.

In more detail, each of the subpixels SP according to one embodiment can include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering one edge of the pixel electrode 114, the organic light emitting layer 116 on the pixel electrode 114 and the bank 115, a reflective electrode 117 on the organic light emitting layer 116, and an encapsulation layer 118 on the reflective electrode 117.

The circuit element layer 111 can be disposed with thin film transistors 112 for driving each of the plurality of subpixels SP. The circuit element layer 111 can be expressed as the term of an inorganic film layer. The buffer layer BL can be included in the circuit element layer 111 together with the gate insulating layer 111a, the interlayer insulating layer 111b and the passivation layer 111c. The pixel electrode 114, the organic light emitting layer 116 and the reflective electrode 117 can be included in the light emitting element layer E.

The buffer layer BL can be formed between the substrate 110 and the gate insulating layer 111a to protect the thin film transistor 112. The buffer layer BL can be disposed on the entire surface (or front surface) of the substrate 110. The pixel power line EVDD for pixel driving can be disposed between the buffer layer BL and the substrate 110. The pixel power line EVDD can be disposed below the bank 115 while being spaced apart from the thin film transistor 112. The buffer layer BL can serve to block diffusion of a material contained in the substrate 110 into a transistor layer during a high temperature process of a manufacturing process of the thin film transistor. Optionally, the buffer layer BL can be omitted in some cases.

The thin film transistor 112 (or a drive transistor) according to an example can include an active layer 112a, a gate electrode 112b, a source electrode 112c, and a drain electrode 112d.

The active layer 112a can include a channel area, a drain area and a source area, which are formed in a thin film transistor area of a circuit area of the subpixel SP. The drain area and the source area can be spaced apart from each other with the channel area interposed therebetween.

The active layer 112a can be formed of a semiconductor material based on any one of amorphous silicon, polycrystalline silicon, oxide and organic material.

The gate insulating layer 111a can be formed on the channel area of the active layer 112a. As an example, the gate insulating layer 111a can be formed in an island shape only on the channel area of the active layer 112a, or can be formed on an entire front surface of the substrate 110 or the buffer layer BL, which includes the active layer 112a.

The gate electrode 112b can be formed on the gate insulating layer 111a to overlap the channel area of the active layer 112a.

The interlayer insulating layer 111b can be formed on the gate electrode 112b and the drain area and the source area of the active layer 112a. As in FIG. 4, the interlayer insulating layer 111b can be formed in the circuit area and an entire light emission area, in which light is emitted to the subpixel SP. However, embodiments of the present disclosure are not limited thereto, the interlayer insulating layer 111b can be patterned between the drain electrode 112d and the gate electrode 112b and drain region of the active layer 112a and can be arranged in an island shape, and moreover, can be patterned between the source electrode 112c and the gate electrode 112b and source region of the active layer 112a and can be arranged in an island shape.

The source electrode 112c can be electrically connected to the source area of the active layer 112a through a source contact hole provided in the interlayer insulating layer 111b overlapped with the source area of the active layer 112a. The drain electrode 112d can be electrically connected to the drain area of the active layer 112a through a drain contact hole provided in the interlayer insulating layer 111b overlapped with the drain area of the active layer 112a.

The drain electrode 112d and the source electrode 112c can be made of the same metal material. For example, each of the drain electrode 112d and the source electrode 112c can be made of a single metal layer, a single layer of an alloy or a multi-layer of two or more layers, which is the same as or different from that of the gate electrode.

Meanwhile, in the display apparatus 100 according to one embodiment of the present disclosure, the substrate 110 can include a connecting area CNA where the thin film transistor 112 and the pixel electrode 114 are connected. The connecting area CNA according to one example is an area where the thin film transistor 112 in the circuit area CA and the pixel electrode 114 are connected. As shown in FIG. 2, the connecting area CNA according to one example can be an area between the light emission area EA and the circuit area CA. Since the connecting area CNA is an area where the thin film transistor 112 and the pixel electrode 114 are connected, the pattern portion 120 may not be formed in the connecting area CNA. This is because if the pattern portion 120 is formed in the connecting area CNA, the thickness of the pixel electrode 114 can be thinned due to a step difference of the pattern portion 120, which can cause the pixel electrode 114 to be short-circuited. Therefore, the display apparatus 100 according to one embodiment of the present disclosure can be provided that the pattern portion 120 is not formed in the connecting area CNA, thereby preventing the connection between the pixel electrode 114 and the thin film transistor 112 from being weakened.

In addition, the circuit area can further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor can be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 can further include a light shielding layer provided below the active layer 112a of at least one of the thin film transistor 112, the first switching thin film transistor or the second switching thin film transistor. The light shielding layer can be disposed between the substrate 110 and the active layer 112a to shield light incident on the active layer 112a through the substrate 110, thereby minimizing a change in the threshold voltage of the transistor due to external light. Further, since the light shielding layer is provided between the substrate 110 and the active layer 112a, the thin film transistor can be prevented from being seen by a user.

The passivation layer 111c can be provided on the substrate 110 to cover the pixel area. The passivation layer 111c covers a drain electrode 112d, a source electrode 112c and a gate electrode 112b of the thin film transistor 112, and the buffer layer BL. The reference line RL can be disposed between the passivation layer 111c and the interlayer insulating layer 111b. The reference line RL can be disposed at a position symmetrical to the pixel power line EVDD based on the light emission area EA or a similar position symmetrical to the pixel power line EVDD.

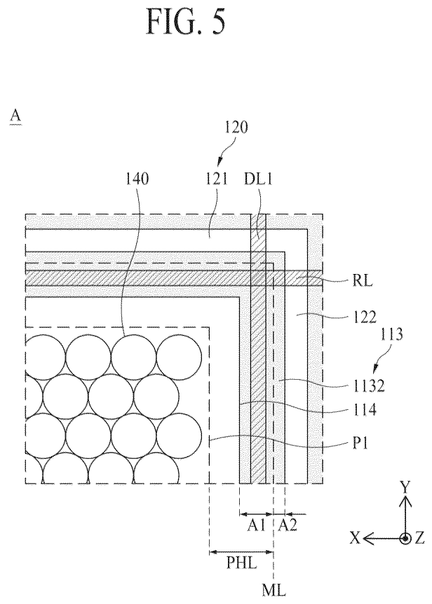

On the other hand, the display apparatus 100 according to one embodiment of the present disclosure can be provided such that the bank 115 is disposed only in the circuit area CA. Accordingly, as shown in FIG. 5, the pixel power lines EVDD can be disposed to overlap the bank 115 in a third direction (e.g., Z-axis direction), and the reference line RL may not overlap the bank 115 in the third direction (Z-axis direction). The reference line RL can be on the same layer as the source and drain electrodes 112c, 112d. The passivation layer 111c can be formed over the circuit area and the light emission area. The passivation layer 111c can be omitted. The color filter CF can be disposed on the passivation layer 111c.

The overcoat layer 113 can be provided on the substrate 110 to cover the passivation layer 111c and the color filter CF. When the passivation layer 111c is omitted, the overcoat layer 113 can be provided on the substrate 110 to cover the circuit area. The overcoat layer 113 can be formed in the circuit area CA in which the thin film transistor 112 is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

The overcoat layer 113 formed in the display area DA (or the light emission area EA) can include a plurality of concave portions 140. The plurality of concave portions 140 can be a configuration to increase the light efficiency of the light emission area EA and formed inside the overcoat layer 113. In detail, as shown in FIG. 4, the plurality of concave portions 140 can be formed in a concave shape on the first layer 1131 of the overcoat layer 113. The plurality of concave portions 140 are provided to be connected to each other so that an embossed shape can be formed in the first layer 1131.

The second layer 1132 having a refractive index higher than that of the first layer 1131 can be formed on the first layer 1131. A path of the light, which is directed toward the adjacent subpixel SP, among the light emitted from the light emitting element layer E can be changed toward the reflective portion 130 in accordance with a difference in the refractive index between the second layer 1132 and the first layer 1131. The second layer 1132 can be provided to cover the embossed shape of the first layer 1131 and thus the upper surface 1132a can be provided to be flat.

The pixel electrode 114 is formed on the upper surface 1132a of the second layer 1132 so that the pixel electrode 114 can be provided to be flat, and the organic light emitting layer 116 and the reflective electrode 117, which are formed on the pixel electrode 114, can be provided to be also flat. Since the pixel electrode 114, the organic light emitting layer 116, the reflective electrode 117, for example, the light emitting element layer E is provided to be flat in the light emission area EA, a thickness of each of the pixel electrode 114, the organic light emitting layer 116 and the reflective electrode 117 in the light emission area EA can be uniformly formed. Therefore, the organic light emitting layer 116 can be uniformly emitted without deviation in the light emission area EA.

The plurality of concave portions 140 can be formed on the first layer 1131 through a photo process using a mask having an opening portion and then a pattern (or etching) or ashing process after the first layer 1131 is coated to cover the passivation layer 111c and the color filter CF. The plurality of concave portions 140 can be formed in areas that overlap with the color filter CF or can be formed in areas that do not overlap with the bank 115 of non-light emission areas NEA.

Referring back to FIG. 4, the color filter CF disposed in the light emission area EA can be provided between the substrate 110 and the overcoat layer 113. Therefore, the color filter CF can be disposed between the pixel power line EVDD, for example, the pixel power line EVDD and the reflective portion 130 or between the pixel driving line and the pattern portion 120. The color filter CF can include a red color filter (or a first color filter) CF1 for converting white light emitted from the organic light emitting layer 116 into red light, a green color filter (or a second color filter) CF2 for converting white light into green light, and a blue color filter (or a third color filter) CF3 for converting white light into blue light. The fourth subpixel, which is a white subpixel, may not include a color filter since the organic light emitting layer 116 emits white light.

As shown in FIG. 3, the display apparatus 100 according to one embodiment of the present disclosure can be provided such that color filters having different colors partially overlap each other at a boundary portion of the plurality of subpixels SP. In this case, the display apparatus 100 according to one embodiment of the present disclosure can prevent the light emitted from each subpixel SP from being emitted to the adjacent subpixel SP due to the color filters overlapped with each other at the boundary portion of the subpixels SP, thereby preventing color mixture between the subpixels SP from occurring.

Referring back to FIG. 4, the pixel electrode 114 of the subpixel SP can be formed on the overcoat layer 113. The pixel electrode 114 can be connected to a drain electrode or a source electrode of the thin film transistor 112 through a contact hole passing through the overcoat layer 113 and the passivation layer 111c. In FIG. 4, the pixel electrode 114 can be provided to be wider than the second layer 1132. However, the pixel electrode 114 can be provided to be narrower than the second layer 1132 in accordance with the cross-section position. For example, as shown in FIG. 4, the pixel electrode 114 can be provided to be narrower than the second layer 1132. As shown in FIG. 5, when the pixel electrode 114 is provided to be wider than the second layer 1132, an edge portion of the pixel electrode 114 can be connected to the drain electrode or the source electrode in the circuit area CA. In this case, the edge portion of the pixel electrode 114 can be covered by the bank 115. The pixel electrode 114 can be made of at least one of a transparent metal material or a semi-transmissive metal material.

Since the display apparatus 100 according to an embodiment of the present disclosure is configured as the bottom emission type, the pixel electrode 114 can be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 can include MoTi. The pixel electrode 114 can be a first electrode or an anode electrode.

The bank 115 is a non-light emission area, which can be disposed on one side of each of the light emitting portions (or the concave portions 140) of each of the plurality of subpixels SP. For example, the bank 115 can be disposed in a circuit area CA. As shown in FIG. 4, the bank 115 can be formed to cover the portion where an edge of each of the pixel electrodes 114 of each of the subpixels SP connects to the thin film transistor 112. For example, the bank 115 can partially cover the pixel electrodes 114. Accordingly, the bank 115 can prevent the pixel electrode 114 and the reflective electrode 117 from contacting in the circuit area CA. The exposed portion of the pixel electrode 114 that is not covered by the bank 115 can include a light emitting portion (or the light emission area EA). Such the light emitting portion can be formed on a plurality of concave portions 140, as shown in FIG. 3, so that the light emitting portion (or light emission areas EA) can overlap the concave portions 140 in the thickness direction (or the third direction (Z-axis direction)) of the substrate 110.

After the bank 115 is formed, the organic light emitting layer 116 can be formed to cover the pixel electrode 114 and the bank 115. Therefore, the bank 115 can be provided between the pixel electrode 114 and the organic light emitting layer 116. The bank 115 can be expressed as the term of a pixel defining layer. The banks 115 according to one example can include organic and/or inorganic material. The banks 115 according to one example can be concave or sloped along the profile of the pattern portion 120 (or second layer 1132).

Referring again to FIG. 4, the organic light emitting layer 116 can be formed on the pixel electrode 114 and the bank 115. The organic light emitting layer 116, according to one example, can be disposed in the light emission area EA and the non-light emission area NEA. The organic light emitting layer 116 can be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 can emit light. The organic light emitting layer 116 can be formed of a plurality of subpixels SP and a common layer provided on the bank 115.

The organic light emitting layer 116 according to an embodiment can be provided to emit white light. The organic light emitting layer 116 can include a plurality of stacks which emit lights of different colors. For example, the organic light emitting layer 116 can include a first stack, a second stack, and a charge generating layer (CGL) provided between the first stack and the second stack. The light emitting layer can be provided to emit the white light, and thus, each of the plurality of subpixels SP can include a color filter CF suitable for a corresponding color.

The first stack can be provided on the pixel electrode 114 and can be implemented a structure where a hole injection layer (HIL), a hole transport layer (HTL), an emission layer (EML(B)), and an electron transport layer (ETL) are sequentially stacked.

The charge generating layer can supply an electric charge to the first stack and the second stack. The charge generating layer can include an N-type charge generating layer for supplying an electron to the first stack and a P-type charge generating layer for supplying a hole to the second stack. The N-type charge generating layer can include a metal material as a dopant.

The second stack can be provided on the first stack and can be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack can be arranged all over the plurality of subpixels SP. The organic light emitting layer 116 according to other example can be provided in a three-stack structure or a four-stack structure, depending on the number of stacks stacked.

The reflective electrode 117 can be formed on the organic light emitting layer 116. The reflective electrode 117 can be disposed in a light emission area EA and a non-light emission area NEA. The reflective electrode 117 according to one example can include a metal material. The reflective electrode 117 can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 can be made of a metal material having high reflectance. The reflective electrode 117 according to one example can be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy can be an alloy such as silver (Ag), palladium (Pd) and copper (Cu). The reflective electrode 117 can be expressed as terms such as a second electrode, a cathode electrode and a counter electrode.

Meanwhile, in the display apparatus 100 according to one embodiment of the present disclosure, the reflective portion 130 can be a portion of the reflective electrode 117. Therefore, the reflective portion 130 can reflect light, which is directed toward the adjacent subpixel SP, toward the light emission area EA of the subpixel SP for emitting light. Since the reflective portion 130 is a portion of the reflection electrode 117, as shown in FIG. 3, the reflective portion 130 can be denoted by a reference numeral 117a. In the present disclosure, the reflective portion 130 can mean the reflective electrode 117 that overlaps the pattern portion 120. In particular, the reflective portion 130 can mean the reflective electrode 117 that is inclined while being overlapped with the pattern portion 120. Accordingly, the reflective portion 130 can reflect light, which is directed toward neighboring subpixels, and/or light, which is extinction via total reflection between the interface, to the light emission area EA of the emitting subpixel SP and/or non-light emission area NEA, as shown in FIG. 3.

The encapsulation layer 118 is formed on the reflective electrode 117. The encapsulation layer 118 serves to prevent oxygen or moisture from being permeated into the organic light emitting layer 116 and the reflective electrode 117. To this end, the encapsulation layer 118 can include at least one inorganic film and at least one organic film.

Meanwhile, as shown in FIG. 3, the encapsulation layer 118 can be disposed not only in the light emission area EA but also in the non-light emission area NEA. The encapsulation layer 118 can be disposed between the reflective electrode 117 and the opposite substrate 200.

Hereinafter, the pattern portion 120 and the reflective portion 130 of the display apparatus 100 according to one embodiment of the present disclosure will be described in more detail with reference to FIGS. 2 and 3.

The display apparatus 100 according to one embodiment of the present disclosure can be provided with a pattern portion 120 on a periphery of the light emission area EA (or non-light emission area NEA) and a reflective portion 130 disposed on the pattern portion 120, for preventing light extraction efficiency from decreasing as some of the light emitted from the emitting element layer may not be emitted to the outside due to total reflection or the like at the interface between the emitting element layer and the electrode. The reflective portion 130 can be inclinedly disposed along a profile of the pattern portion 120.

Referring to FIG. 2, the pattern portions 120 can be concavely formed in the first layer 1131 of the overcoat layer 113. The pattern portion 120 can be disposed in a non-light emission area NEA, as shown in FIG. 2. For example, the pattern portion 120 can be disposed to surround the light emission area EA while being adjacent to a plurality of concave portions 140. The pattern portion 120 can be formed together in the non-light emission area NEA when the plurality of concave portions 140 are formed in the light emission area EA. The pattern portion 120 can include a bottom surface 120b and an inclined surface 120s.

The bottom surface 120b of the pattern portion 120 according to one embodiment is a surface formed to be closest to the substrate 110, or can be disposed to be closer to the substrate 110 (or the upper surface of the substrate) than the pixel electrode 114 (or the lower surface of the pixel electrode 114) in the light emission area EA.

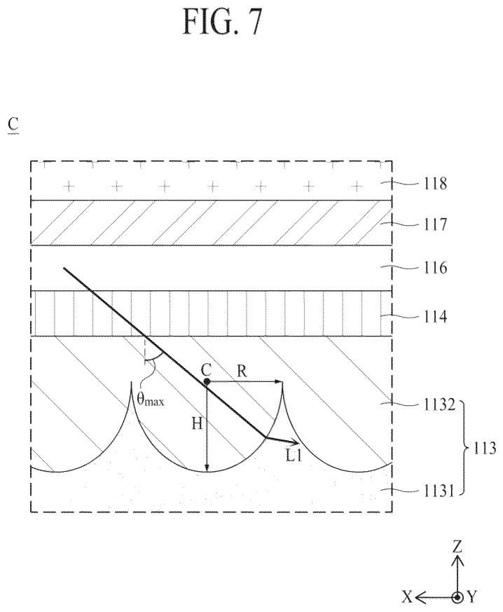

As shown in FIG. 3, the bottom surface 120b of the pattern portion 120 (or the flat (upper) surface 1131a of the first layer 1131) can be deeper than a depth (H, shown in FIG. 7) of each of the plurality of concave portions 140. Here, the depth of each of the plurality of concave portions 140 can be a length from a center C of the concave portion 140 to an outer surface of the concave portion 140 (or an interface between the first layer 1131 and the second layer 1132) in a vertical direction (or the third direction (Z-axis direction)). As shown in FIG. 3, the flat (upper) surface 1131a of the first layer 1131 can be disposed closer to the substrate 110 than the plurality of concave portions 140.

By having the bottom surface 120b of the pattern portion 120 or the flat (upper) surface 1131a of the first layer 1131 deeper than the depth (H, shown in FIG. 7) of each of the plurality of concave portions 140, light refracted through at least one concave portion 140 of the plurality of concave portions 140 can be totally reflected at the interface between the flat (upper) surface 1131a of the first layer 1131 and the second layer 1132, as shown in FIG. 3. Thus, in the display apparatus 100 according to one embodiment of the present disclosure, the plurality of concave portions 140 can be spaced apart from the reflective portion 130, as the amount of light totally reflected can vary depending on the area (or length) of the flat (upper) surface 1131a of the first layer 1131 between the outermost concave portion 140 of the plurality of concave portions 140 and the reflective portion 130.

For example, the distance at which the plurality of concave portions 140 are spaced apart from the reflective portion 130 can be greater than the distance at which the edge of the pixel electrode 114 is spaced apart from the reflective portion 130. Referring to FIG. 3, if the shortest horizontal distance at which the edge of the pixel electrode 114 and the reflective portion 130 are spaced apart in the first direction (X-axis direction) is referred to as the first horizontal distance D1, the shortest horizontal distance at which the plurality of concave portions 140 and the reflective portion 130 are spaced apart in the first direction (X-axis direction) can be a second horizontal distance D2 that is longer than the first horizontal distance D1. Thus, the second horizontal distance D2 and the first horizontal distance D1 can have a difference of at least the third horizontal distance D3.

The display apparatus 100 according to one embodiment of the present disclosure has the plurality of concave portions 140 spaced further apart than the edge of the pixel electrode 114 by a third horizontal distance D3 from the reflecting electrode 130, such that light refracted by at least one of the concave portions 140 can be totally reflected from the flat (upper) surface 1131a of the first layer 1131. Accordingly, the display apparatus 100 according to one embodiment of the present disclosure can improve light extraction efficiency as light totally reflected by the flat (upper) surface 1131a of the first layer 1131 can be reflected by the reflective portion 130 disposed in the non-light emission area NEA and projected toward the substrate 110.

On the other hand, as shown in FIG. 3, the first horizontal distance D1 is the shortest horizontal distance between the edge of the pixel electrode 114 and the reflective portion 130, and thus can be defined as the width of the first area A1 adjacent to the light emission area EA.

Referring again to FIG. 3, when the depth of the pattern portion 120 is lower than the depth of the concave portion 140, the area of the reflective portion 130 disposed inclined to the non-light emission area NEA becomes smaller, and thus, light extraction efficiency can be reduced. Therefore, the display apparatus 100 according to one embodiment of the present disclosure can be provided with a depth of the pattern portion 120 deeper than the depth of the concave portion 140, thus light extraction efficiency can be improved by increasing the reflecting area of the reflective portion 130.

The inclined surface 120s of the pattern portion 120 can be disposed between the bottom surface 120b and the plurality of concave portions 140. Thus, the inclined surface 120s of the pattern portion 120 can be provided to surround the light emission area EA or the plurality of concave portions 140. As shown in FIG. 3, the inclined surface 120s can be connected to the bottom surface 120b. The inclined surface 120s can form a predetermined angle with the bottom surface 120b. For example, the angle formed by the inclined surface 120s and the bottom surface 120b can be an obtuse angle. Accordingly, the pattern portion 120 can be provided that the width of the pattern portion 120 decreases from the opposite substrate 200 (or the reflective portion 130) toward the substrate 110 (or in the third direction (Z-axis direction)).

As the inclined surface 120s and the bottom surface 120b of the pattern portion 120 form an obtuse angle, the organic light emitting layer 116 and the reflective electrode 117 formed in the subsequent process can be concave along the profile of the pattern portion 120. Thus, the reflective portion 130 included in the reflective electrode 117 can be concavely (or inclinedly) formed on the pattern portion 120 concavely (or inclinedly) formed in the non-light emission area NEA (or surrounding area).

As shown in FIG. 3, the pattern portion 120 can be provided to surround the light emission area EA. As the pattern portion 120 is provided to surround the light emission area EA, at least a portion of the reflective portion 130 disposed to be inclined on the pattern portion 120 can be provided to surround the light emission area EA. Therefore, in the display apparatus 100 according to one embodiment of the present disclosure, since light can be extracted even from the non-light emission area NEA near the light emission area EA, overall light efficiency can be improved. Therefore, the display apparatus 100 according to one embodiment of the present disclosure can have the same light emission efficiency or more improved light emission efficiency even with low power as compared with a general display apparatus having no pattern portion 120 and reflective portion 130 on the pattern portion 120, whereby overall power consumption can be reduced.

In addition, the display apparatus 100 according to one embodiment of the present disclosure can allow the light emitting element layer E to emit light even with low power, thereby improving lifespan of the light emitting element layer E.

Referring back to FIG. 2, the pattern portion 120 can include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 can mean the pattern portion 120 disposed in a horizontal direction, and the second pattern line 122 can mean the pattern portion 120 disposed in a vertical direction.

The first pattern line 121 can include a bottom surface 121b and an inclined surface 121s. The second pattern line 122 can include a bottom surface 122b and an inclined surface 122s. Since each of the bottom surface 121b and the inclined surface 121s of the first pattern line 121 and each of the bottom surface 122b and the inclined surface 122s of the second pattern line 122 are the same as each of the bottom surface 120b and the inclined surface 120s of the pattern portion 120, their description will be replaced with the description of the bottom surface 120b and the inclined surface 120s of the pattern portion 120. The first pattern line 121 and the second pattern line 122 can be connected to one in the non-light emission area NEA (or the peripheral area) to surround the light emission area EA.

The first pattern line 121 can be disposed between the subpixels SP for emitting light of the same color. For example, the first pattern line 121 can be disposed between the first subpixels SP1 disposed in the second direction (Y-axis direction). Therefore, the first pattern line 121 can be disposed in the first direction (X-axis direction). In contrast, the second pattern line 122 can be disposed between the subpixels SP for emitting light of different colors. For example, the second pattern line 122 can be disposed between the first subpixel SP1 that is a red subpixel, and the second subpixel SP2 that is a green pixel. Therefore, the second pattern line 122 can be disposed in the second direction (Y-axis direction).

Since the second pattern line 122 is disposed between the subpixels SP for emitting light of different colors, the reflective portion 130 on the second pattern line 122 can prevent light of different colors from being emitted to other adjacent subpixels SP. Therefore, the display apparatus 100 according to the present disclosure can prevent color mixture (or color distortion) between the subpixels SP for emitting light of different colors, thereby improving color purity.

Further, since the second pattern line 122 is extended in the second direction (Y-axis direction) between the subpixels SP emitting different colors, the second pattern line 122 may not overlap the data line (e.g., the first data line DL1) in the second direction (Y-axis direction). In contrast, the first pattern line 121 is extended in the first direction (X-axis direction), thus the first pattern line 121 can partially overlap the data line (e.g., the first data line DL1) in the second direction (Y-axis direction).

On the other hand, since the pattern portion 120 is formed by patterning the second layer 1132 of the overcoat layer 113, an end 1132b of the second layer 1132 can contact the flat surface 1131a of the first layer 1131, as shown in FIG. 3. However, in this case, the end 1132b of the second layer 1132 can only contact a portion of the flat surface 1131a. This is because, if the second layer 1132 covers the entire flat surface 1131a, the depth of the reflective portion 130 formed on the pattern portion 120 can be relatively low, which can reduce the reflection efficiency. Therefore, the display apparatus 100 according to one embodiment of the present disclosure is provided that the second layer 1132 does not cover the entire flat surface 1131a of the first layer 1131, but only contacts a portion of the flat surface 1131a, so that the reflective portion 130 formed in a subsequent process can be formed to be disposed close to the bottom surface 120b, thereby improving the reflection efficiency. As shown in FIG. 3, the upper surface 1132a of the second layer 1132 and the end surface 1132b of the second layer 1132 can be connected via an inclined surface 1132c of the second layer 1132. The inclined surface 1132c of the second layer 1132 can be disposed facing the reflective portion 130, according to an example. On the other hand, since the pattern portion 120 is formed by patterning the second layer 1132 of the overcoat layer 113, the inclined surface 120s of the pattern portion 120 can be the inclined surface 1132c of the second layer 1132.

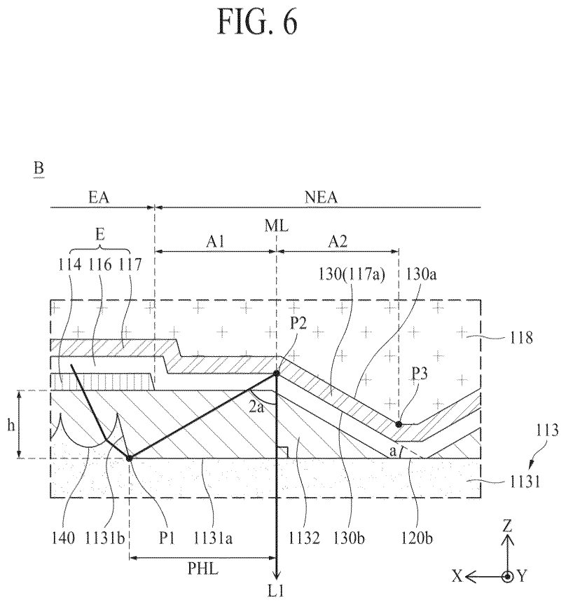

Hereinafter, with reference to FIGS. 5 and 6, the shortest horizontal distance PHL between the reflective portion 130 (or the lower surface 130b of the reflective portion 130) and an end of the upper surface 1131a of the first layer 1131 will be described in detail.

FIG. 5 is a schematic enlarged plan view of portion A shown in FIG. 2, and FIG. 6 is a schematic enlarged cross-sectional view of portion B shown in FIG. 3 according to an example of the present disclosure.

Referring to FIGS. 5 and 6, in the display apparatus 100 according to one embodiment of the present disclosure, the first layer 1131 can further include the inclined surface 1131b connecting the flat surface 1131a and the plurality of concave portions 140 (or outermost concave portions 140). The flat surface 1131a of the first layer 1131 and the inclined surface 1131b of the first layer 1131 can be connected at a first point P1. The first point P1 according to an example can be disposed to overlap with the pixel electrode 114 in a third direction (Z-axis direction), as shown in FIG. 6. This is because, by securing a length (or an area) of the flat surface 1131a of the first layer 1131, the amount of overall reflection of light that is refracted and incident by the concave portion 140 can be increased. By having a long length (or area) of the flat surface 1131a of the first layer 1131 on which the light is totally reflected, the amount of light totally reflected to the reflective portion 130 by the flat surface 1131a of the first layer 1131 can be increased, and thereby improving the efficiency of the front extraction light L1. Accordingly, the display apparatus 100 according to one embodiment of the present disclosure is provided that the first point P1 overlaps the pixel electrode 114 in the third direction (Z-axis direction), so that the amount of light totally reflected by the concave portion 140 can increase, thereby improving the light efficiency.

Referring to FIG. 5, as the first point P1 is provided to overlap with the pixel electrode 114, the first point P1 can be disposed in a plane as a structure surrounding the plurality of concave portions 140 between the plurality of concave portions 140 and the edge of the pixel electrode 114. On the other hand, the first data line DL1 can be disposed to overlap the first area A1 in a second direction (Y-axis direction) not to obscure the light reflected by the reflecting electrode 130 (or the reflective portion 117a) (as shown in FIG. 3). For example, the first data line DL1 can be disposed between the pixel electrode 114 and the reflecting electrode 130. Thus, the display apparatus 100 according to one embodiment of the present disclosure can be prevented from having its light extraction efficiency decreased by the data line. On the other hand, the first area A1 can refer to an area provided between the light emission area EA and the second area A2, or an area of the shortest horizontal distance between the pixel electrode 114 and the reflective portion 130.

Referring to FIG. 6, the reflective portion 130 can include an upper surface 130a that contacts the encapsulation layer 118, and a lower surface 130b that contacts the organic light emitting layer 116. For example, the upper surface 130a can contact the encapsulation layer 118 in the second area A2. And the lower surface 130b can contact the organic light emitting layer 116 in the second area A2. The lower surface 130b of the reflective portion 130 can include a second point P2 disposed uppermost on the pattern portion 120. In one example, the second point P2 can be an inflection point of the reflective electrode 117 that inflects in the pattern portion 120. Alternatively, the second point P2 can be an intersection of the flat lower surface of the reflective electrode 117 (or an extension line of the upper surface of the pixel electrode 114) disposed in the first area A1 and the lower surface 130b of the reflecting electrode 130. A virtual line passing through the second point P2 and parallel to the second direction (Y-axis direction) can be the baseline ML. The baseline ML according to one example can be a baseline separating the first area A1 from the second area A2.

On the other hand, as shown in FIG. 6, the upper surface 130a of the reflective portion 130 can include a third point P3 disposed at lowermost side on the pattern portion 120. In one example, the third point P3 can be a point where the upper surface 130a of the reflective portion 130 connects with the upper surface of the reflective electrode 117 flatly disposed on the pattern portion 120.

In the display apparatus 100 according to one embodiment of the present disclosure, the non-light emission area NEA can include the first area A1 and the second area A2. As shown in FIG. 6, the first area A1 can be an area between an edge of the pixel electrode 114 and the second point P2. The first area A1 can be disposed adjacent to the light emission area EA. The second area A2 can be adjacent to the first area A1 and can be an area between the second point P2 and the third point P3. As shown in FIG. 6, the reflective portion 130 can be disposed in the second area A2. Thus, in the display apparatus 100 according to one embodiment of the present disclosure, light that is refracted through at least one concave portion 140 of the plurality of concave portions 140 and totally reflected by the flat surface 1131a of the first layer 1131 can be reflected by the reflective portion 130 disposed in the second area A2 and projected onto the substrate 110.

On the other hand, in the display apparatus 100 according to one embodiment of the present disclosure, the horizontal distance PHL of the second point P2 and the first point P1 can be provided to satisfy a relationship in the following Equation 1: PHL=h*tan(2a). Here, the horizontal distance PHL of the second point P2 and the first point P1 can refer to the shortest horizontal distance PHL of the second point P2 and the first point P1 in the first direction (X-axis direction). The h can be a thickness of the second layer 1132 disposed on the flat surface 1131a of the first layer 1131. The a can be an angle between the reflective portion 130 (or an extension of the lower surface 130b of the reflective portion 130) and the flat surface 1131a of the first layer 1131 (or the bottom surface 120b of the pattern portion 120).

Thus, the display apparatus 100 according to one embodiment of the present disclosure can be provided with a first layer 1131 and a second layer 1132 and a reflective portion 130 to satisfy the above horizontal distance (PHL), thus light refracted by the concave portion 140 and totally reflected from the flat surface 1131a is reflected by the reflective portion 130 and directed toward the substrate 110. As a result, in the display apparatus 100 according to one embodiment of the present disclosure, the second point P2 and the first point P1 can be provided with a horizontal distance PHL satisfying the mathematical expression PHL=h*tan(2a), and the plurality of concave portions 140 (or the outermost concave portions 140) can be disposed further inwardly toward the center portion of the pixel electrode 114 than the first point P1. Therefore, the display apparatus 100 according to one embodiment of the present disclosure can be provided to have a structure in which the plurality of concave portions 140 are spaced apart from the reflective portion 130 at a distance greater than the above horizontal distance PHL.

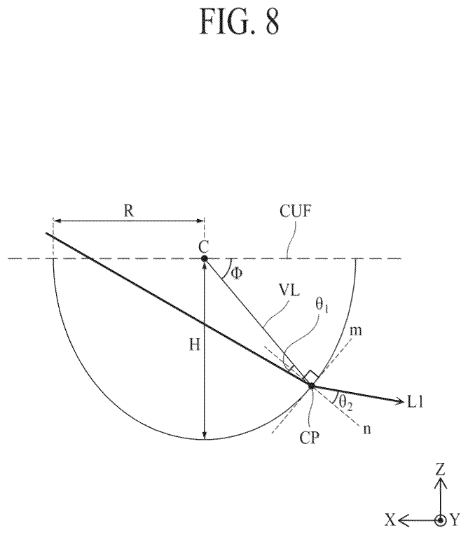

Hereinafter, with reference to FIGS. 7 and 8, the intensity of refracted light I(θₘₐₓ) that reaches the reflective portion 130 after light emitted from the organic light emitting layer 116 is incident on at least one concave portion 140 of the plurality of concave portions and refracted by the at least one concave portion 140 will be described in detail.

Since the light refracted by the concave portion 140 is totally reflected from the flat portion 1131a, the intensity of the refracted light reaching the reflective portion 130, I(θₘₐₓ), can be the same as the intensity of the light totally reflected from the flat portion 1131a. Additionally, light refracted by the concave portion 140 can reach the reflective portion 130 directly without being totally reflected from the flat portion 1131a.

FIG. 7 is a schematic enlarged cross-sectional view of the portion C shown in FIG. 3, and FIG. 8 is a schematic cross-sectional view showing light refraction in one concave portion shown in FIG. 7.

Referring now to FIGS. 7 and 8, in the display apparatus 100 according to one embodiment of the present disclosure, the intensity I(θₘₐₓ) of light refracted by the at least one concave portion 140 is greater than the intensity I₀ of light incident on the concave portion 140, a light transmittance T_{P} at a point in the concave portion 140, and a first angle θₘₐₓ at which light emitted by the organic light emitting layer 116 is incident on the concave portion 140 of any one of the plurality of concaves from a direction perpendicular to the lower surface of the pixel electrode 114, a maximum angle Φ₀ through which light incident at the first angle is transmitted to a side surface of the concave portion 140 without being totally reflected in the interior of the concave portion 140, and a second angle Φ formed between the upper surface of the concave portion 140 and a virtual line VL connecting a point on the concave portion 140 through which light incident on the concave portion 140 is transmitted and a center C of the concave portion 140, which can be derived by mathematical expressions relating the first angle to the second angle Φ.

For example, the intensity of light refracted by the at least one concave portion 140, I(θₘₐₓ), is given by the mathematical expression below (Equation 2):

I(θₘₐₓ)=∫₀^{Φ}^{₀}I₀T_{P}(θₘₐₓ,Φ)dΦ

Here, I(θₘₐₓ) can be provided to satisfy the equation (Equation 2). The letter Φ₀ is a maximum angle at which light incident at the first angle is transmitted to a side surface of the concave portion 140 without being totally reflected in the interior of the concave portion 140, the I₀ is an intensity of light incident on the concave portion 140, and the T_{P} is a light transmittance at a point CP on the concave portion 140, the θₘₐₓ is the first angle at which light emitted by the organic light emitting layer 116 is incident on one concave portion of the plurality of concave portions 140 from a direction perpendicular to the lower surface of the pixel electrode 114, the Φ is a second angle at which a virtual line VL connecting the point CP of the concave portion 140 through which light incident on the concave portion 140 is transmitted and a center C of the concave portion 140 is formed with the upper surface of the concave portion 140. Here, the side surface of the concave portion 140 can refer to an outer surface of the concave portion 140 disposed in a direction other than perpendicular to the center C of the concave portion 140.

Further, referring to FIG. 7, the first angle θₘₐₓ can mean the maximum angle at which light emitted by the organic light emitting layer 116 passes through the pixel electrode 114 and is incident on the second layer 1132 (or the concave portion 140).

Meanwhile, the maximum angle Φ₀ through which light incident at the first angle θₘₐₓ is transmitted to the side surface of the concave portion 140 without being totally reflected in the interior of the concave portion 140 is given by the following mathematical expression (Equation 3), and can be provided to satisfy the following mathematical expression (Equation 3):

$${Φ}_{0} = a tan ( - AR / tan ( {θ}_{max} - a sin ( N ) ) )$$

Here, the maximum angle Φ₀ can be provided to satisfy the mathematical expression (Equation 3).

The AR is an aspect ratio of one concave portion 140 of the plurality of concave portions, the θₘₐₓ is the first angle, and the N is a ratio of a refractive index of the first layer 1131 to a refractive index of the second layer 1132. Here, the aspect ratio is the ratio of a length H of the perpendicular direction from the center C of the concave portion 140 to the periphery of the concave portion 140 to the radius R of the concave portion 140.

In Equation 2 above, the light transmittance T_{P} at the point CP of the concave portion 140 is given by the mathematical expression below (Equation 4):

$${T}_{P} = 1 - ( {\vert \frac{sin {θ}_{1} - N sin {θ}_{2}}{sin {θ}_{1} + N sin {θ}_{2}} \vert}^{2} + {\vert \frac{N sin {θ}_{1} - sin {θ}_{2}}{N sin {θ}_{1} + sin {θ}_{2}} \vert}^{2} )$$

Here, the light transmittance T_{P} can be provided to satisfy the mathematical expression (Equation 4).

The θ₁ is an angle of incidence of light incident on one concave portion 140 of the plurality of concave portions, the θ₂ is a refractive angle of light transmitting through the concave portion 140, and the N is a ratio of the refractive index of the first layer 1131 to the refractive index of the second layer 1132.

The angle of incidence θ₁ of light incident into the concave portion 140 can be an angle between a normal n to a tangent of a point CP of the concave portion 140, through which light incident into the concave portion 140 transmits the concave portion 140, and the light incident into the concave portion 140.

The angle of incidence θ₁ according to one example is given by the mathematical expression below (Equation 5):

$${θ}_{1} = π / 2 - m - {θ}_{max}$$

Here, the angle of incidence θ₁ can be provided to satisfy the mathematical expression (Equation 5).

The π is 3.14, the m is a slope of the tangent of the point CP of the concave portion 140, through which light incident into the concave portion 140, and the θₘₐₓ is a first angle.

The angle of refraction θ₂ of the light transmitting through the concave portion 140 can be an angle between the light transmitting through the concave portion 140 and the normal n (or the slope of the normal n).

The refraction angle θ₂ according to one example is given by the equation below (Equation 6):

θ₂=a sin(N sin(θ₁))

Here, the refraction angle θ₂ can be provided to satisfy the mathematical expression (Equation 6).

The N is the ratio of the refractive index of the first layer 1131 to the refractive index of the second layer 1132, and the θ₁ is the angle of incidence of light incident on the concave portion 140.

In Equation 5 above, the slope m of the tangent of the point CP of the concave portion 140, through which light transmits, is equal to the following equation (Equation 7):

$$m = \vert atan ( - \frac{cos Φ}{sin Φ} AR ) \vert$$

Here, the slope m can be provided to satisfy the mathematical expression (Equation 7).

The AR is the aspect ratio of one concave portion 140 of the plurality of concave portions, and the Φ is the second angle that the virtual line VL connecting a point CP of the concave portion 140 through which light incident on the concave portion 140 is transmitted and a center C of the concave portion 140 forms with an upper surface CUF of the concave portion 140. The upper surface CUF of the concave portion 140 according to one example can refer to an imaginary plane (or virtual line) disposed in a plane equal to a radius R through the center C of the concave portion 140, as shown in FIG. 8. For example, in FIG. 8, the upper face CUF of the concave portion 140 can be an imaginary face (or imaginary line) that passes through the center C of the concave portion 140 in the first direction (X-axis direction).

The display apparatus 100 according to one embodiment of the present disclosure is provided with the first layer 1131, the second layer 1132, and the concave portions 140 to satisfy Equation 2 to Equation 7, thus light incident on one of the plurality of concave portions 140 can be refracted to an adjacent concave portion 140 by the periphery of the concave portion 140, as shown in FIG. 7. However, and not necessarily limited thereto, the display apparatus 100 according to one embodiment of the present disclosure can be provided with the first layer 1131, the second layer 1132, and the concave portion 140 to satisfy Equation 2 to Equation 7, thus light incident on one concave portion 140 of the plurality of concaves can be refracted directly to the reflective portion 130 by the outer surface of the concave portion 140.

On the other hand, according to the above mathematical expressions (Equation 2 to Equation 7), the transmittance of the concave portion 140 can be determined according to the aspect ratio AR of the concave portion 140. Since the angle of incidence of the light is changed depending on the aspect ratio AR of the concave portion 140, the display apparatus 100 according to one embodiment of the present disclosure can vary the light transmittance of the concave portion 140 depending on the aspect ratio AR of the concave portion 140 to prevent light from being totally reflected in the concave portion 140 and not being able to be directed to the outside of the substrate 110. Therefore, the inventor who invented the display apparatus 100 according to one embodiment of the present disclosure calculated the amount of light transmitting through the concave portion 140 depending on the angle of incidence according to the aspect ratio AR of the concave portion 140, and derived a light efficiency (or light efficiency increase rate) for the aspect ratio AR of the concave portion 140.

Specifically, the inventor of the display apparatus 100 of the present disclosure can know the intensity of the refracted light that is refracted by the at least one concave portion 140 and reaches the reflective portion 130 (or the baseline ML) through Equation 2 to Equation 7 above, and accordingly, the inventor varied the aspect ratio AR of the concave portion 140 to derive a graph regarding the intensity of the refracted light.

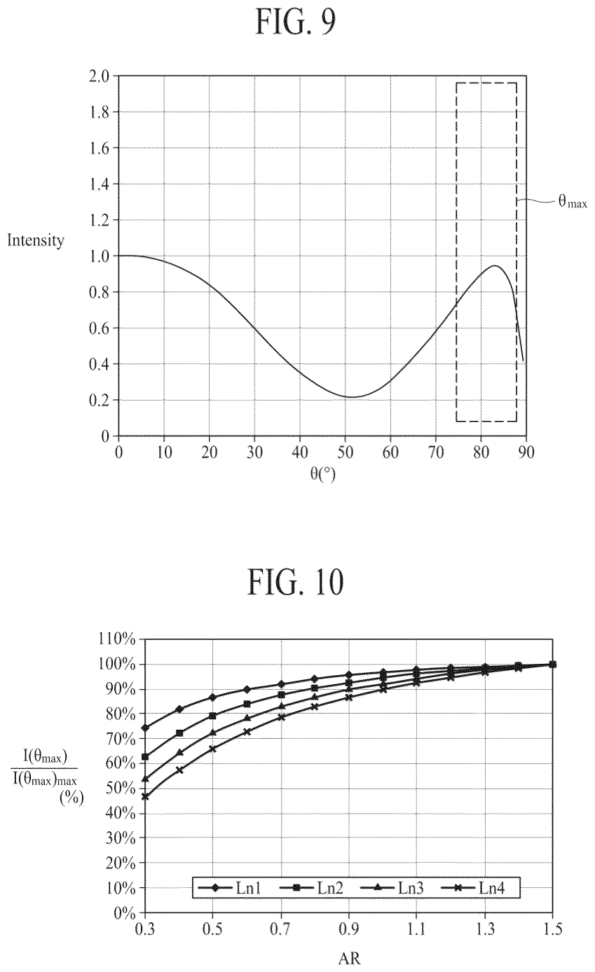

Hereinafter, with reference to FIGS. 9 and 10, light intensity as a function of the angle of light incident on the concave portion 140, and the ratio of refracted light intensity as a function of the aspect ratio of the concave portion 140 will be described in detail.

FIG. 9 is a graph illustrating light intensity as a function of an angle of light incident on a concave portion of a display apparatus according to one embodiment of the present disclosure, and FIG. 10 is a graph illustrating a ratio of refracted light intensity as a function of an aspect ratio of a concave portion of a display apparatus according to one embodiment of the present disclosure.

Referring to FIG. 9, in the display apparatus 100 according to one embodiment of the present disclosure, the first angle θₘₐₓ is a maximum angle at which light emitted by the organic light emitting layer 116 is incident on one concave portion 140 of the plurality of concave portions from a direction perpendicular to the lower surface of the pixel electrode 114. The angle at which the light emitted by the organic light emitting layer 116 is incident on one of the concave portions 140 can vary, and the reason for setting it as a maximum angle is that rather than reflecting the light intensity at all angles, reflecting the light intensity at the angle of the peak point seen in the light distribution of the device has a higher value than the light intensity at other angles.

Referring to FIG. 9 to describe the light intensity as a function of the angle of light incident on the concave portion 140, the horizontal axis represents the angle of light incident on the concave portion 140, i.e., θ, and the vertical axis represents the light intensity. Assuming that the angle of light incident on the concave portion 140 is the angle of incidence, as shown in FIG. 9, the light intensity is 1 when the angle of incidence is 0 degrees (°). As shown in the graph in FIG. 9, the light intensity trends downward from 0 degrees to about 52 degrees, then upward from about 52 degrees to about 83 degrees, and then downward again from about 83 degrees and above. Thus, it can be seen that at an incident angle of about 83 degrees, the light intensity is about 0.95 In FIG. 9, it is described as having a maximum light intensity at about 83 degrees, but it is not limited thereto, and the maximum light intensity can vary depending on the light distribution of the emitting light-emitting element. As a result, the inventor who invented the display apparatus 100 according to the present disclosure derived the above-mentioned Equation 2 to Equation 7 based on having a maximum light intensity when the first angle θₘₐₓ incident on the concave portion 140 is a maximum angle.

FIG. 10 illustrates a ratio of the intensity of refracted light depending on an aspect ratio of a concave portion of a display apparatus according to one embodiment of the present disclosure, the horizontal axis indicates an aspect ratio AR of the concave portion 140, and the vertical axis indicates a ratio (I(θₘₐₓ)/I(θₘₐₓ)ₘₐₓ) of an intensity of refracted light (I(θₘₐₓ)) incident on the reflective portion 130 to a maximum intensity of refracted light (I(θₘₐₓ)ₘₐₓ). For example, if the maximum intensity of refracted light incident on the reflective portion 130 (I(θₘₐₓ)ₘₐₓ) is called 100, and the intensity of refracted light incident on the reflective portion 130 (I(θₘₐₓ)) is called 10, the ratio of the intensities of refracted light can be 10%. The ratio of the intensity of the refracted light incident on the reflective portion 130 (I(θₘₐₓ)) to the maximum intensity of the refracted light (I(θₘₐₓ)ₘₐₓ) is shown on the vertical axis of FIG. 10 as (I(θₘₐₓ)/I(θₘₐₓ)ₘₐₓ), but because it is a ratio, it can be a value of I(θₘₐₓ)/I(θₘₐₓ)ₘₐₓ multiplied by 100.

Referring again to FIG. 10, the uppermost first line Ln1 is a line indicating the ratio of the intensity of the refracted light according to the aspect ratio AR of the concave portion 140 when the first angle θₘₐₓ is 70 degrees. The second line Ln2 immediately below the first line Ln1 is a line indicating the ratio of the intensity of the refracted light according to the aspect ratio AR of the concave portion 140 when the first angle θₘₐₓ is 75 degrees. The third line Ln3 immediately below the second line Ln2 is a line indicating the ratio of the intensity of the refracted light according to the aspect ratio AR of the concave portion 140 when the first angle θₘₐₓ is 80 degrees. The fourth line Ln4 immediately below the third line Ln3 is a line indicating the ratio of the intensity of the refracted light according to the aspect ratio AR of the concave portion 140 when the first angle θₘₐₓ is 85 degrees.

As shown in FIG. 10, it can be seen that when the aspect ratio AR of the concave portion 140 is more than or equal to 1.0, all of the first line Ln1 to the fourth line Ln4 have a ratio of the intensity of the refracted light ((I(θₘₐₓ)/I(θₘₐₓ)ₘₐₓ) more than or equal to 90%. For example, the intensity of the refracted light tends to converge to a certain maximum value as the aspect ratio AR of the concave portion 140 increases. Therefore, the display apparatus 100 according to one embodiment of the present disclosure can be provided with an aspect ratio AR of each of the plurality of concave portions 140 of 1 or more, thus the intensity I(θₘₐₓ) of refracted light reaching the reflective portion 130 can be more than or equal to 90% relative to the maximum intensity (I(θₘₐₓ)ₘₐₓ) of refracted light, thereby maximizing the efficiency of light extraction through the reflective portion 130.

As a result, the display apparatus 100 according to one embodiment of the present disclosure is provided with the shape of the plurality of concave portions 140 (e.g., an aspect ratio (AR) of greater than or equal to 1), and the first layer 1131 and the second layer 1132 (e.g., a ratio of the refractive indices of the first layer 1131 and the second layer 1132) to satisfy Equation 2 to Equation 7 above, since light having an intensity (I(θₘₐₓ)) of refracted light more than or equal to 90% among the light incident on the concave portion 140 relative to the maximum intensity (I(θₘₐₓ)ₘₐₓ) of refracted light can be refracted toward the reflective portion 130, the light extraction efficiency (or frontal light extraction efficiency) can be improved.

Further, the display apparatus 100 according to one embodiment of the present disclosure is provided with the shortest horizontal distance (PHL) between the reflective portion 130 (or the lower surface 130b of the reflective portion 130) and an end of the upper surface 1131a of the first layer 1131 to satisfy Equation 1 above, the light refracted through the at least one concave portion 140 can be provided to be reflected by the reflective portion 130 after being totally reflected from the upper surface 1131a of the first layer 1131 (or the boundary between the first layer 1131 and the second layer 1132). Thus, the display apparatus 100 according to one embodiment of the present disclosure can maximize light extraction efficiency (or frontal light extraction efficiency), due to the reflective portion 130, and the flat surface 1131a of the first layer 1131 which is disposed at the shortest horizontal distance (PHL) between the reflective portion 130 (or the lower surface 130b of the reflective portion 130) and an end of the upper surface 1131a of the first layer 1131.

The display apparatus of the present disclosure can have the plurality of concave portions spaced further apart from the reflective portion disposed in the non-light emission area than the edge of the pixel electrode, such that light extraction efficiency in the non-emission area can be improved through light refraction through the at least one concave portion.

Moreover, since the display apparatus of the present disclosure can extract light even in the non-light emission area, it can have the same luminous efficiency or even better luminous efficiency with lower power compared to a display device without the reflective portion, thereby reducing overall power consumption.

Moreover, the display apparatus of the present disclosure can have an aspect ratio of each of the plurality of concave portions included in each of the plurality of subpixels greater than 1, thereby maximizing the light extraction efficiency of light emitted from the light-emitting element layer.

The effects to be obtained from the present disclosure are not limited to those mentioned above, and other effects not mentioned will be apparent to one of ordinary skill in the art from the description.

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this disclosure should be construed to be included within the scope of the claims of this disclosure.

What is claimed is:

1. A display apparatus comprising:
a plurality of pixels having a plurality of subpixels on a substrate, wherein the substrate includes a light emission area and a non-light emission area adjacent to the light emission area;
a pattern portion disposed on the substrate to be concave in the non-light emission area between the plurality of subpixels; and
a reflective portion disposed to be inclined on the pattern portion,
wherein each of the plurality of sub-pixels includes:
a plurality of concave portions disposed in the light emission area; and
a pixel electrode disposed on the plurality of concave portions, and
wherein a separation distance between the plurality of concave portions and the reflective portion is longer than a separation distance between the pixel electrode and the reflective portion.

2. The display apparatus of claim 1, wherein an outermost concave portion of the plurality of concave portions is spaced apart from an edge of the pixel electrode.

3. The display apparatus of claim 1, wherein
the plurality of subpixels include an overcoat layer including a first layer and a second layer on the first layer, the first layer including the plurality of concave portions,
the first layer includes a flat surface disposed in parallel with the substrate, and
the flat surface is disposed to be closer to the substrate than the plurality of concave portions.

4. The display apparatus of claim 1, wherein the pattern portion is spaced apart from the light emission area.

5. The display apparatus of claim 1, wherein a width of the pattern portion decreases in a direction from the reflective portion toward the substrate.

6. The display apparatus of claim 3, wherein
the first layer includes an inclined surface connecting the flat surface and the plurality of concave portions,
the flat surface of the first layer and the inclined surface of the first layer are connected at a first point, and
the first point is disposed to overlap the pixel electrode.

7. The display apparatus of claim 6, wherein the plurality of subpixels include:
an organic light emitting layer in the light emission area and the non-light emission area; and
a reflective electrode on the organic light emitting layer, and
wherein the reflective portion is a portion of the reflective electrode.

8. The display apparatus of claim 7, wherein
the reflective portion includes a lower surface contacting the organic light emitting layer,
the lower surface of the reflective portion includes a second point disposed on the pattern portion, and
the second point is an inflection point at which the reflective electrode is inflected in the pattern portion.

9. The display apparatus of claim 8, wherein
an upper surface of the reflective portion includes a third point disposed at a lowermost side on the pattern portion,
the non-light emission area includes a first area between an edge of the pixel electrode and the second point, and a second area between the second point and the third point, the second area being adjacent to the first area, and
the reflective portion is disposed in the second area.

10. The display apparatus of claim 9, wherein
a horizontal distance PHL between the second point and the first point is provided to satisfy a following expression:
$$PHL = h * tan ( 2 a ) ,$$
wherein h represents a thickness of the second layer disposed on the flat surface of the first layer, and a represents an angle between the reflective portion and the flat surface of the first layer.

11. The display apparatus of claim 10, wherein the plurality of concave portions are spaced apart from the reflective portion by a distance greater than the horizontal distance.

12. The display apparatus of claim 10, further comprising:
a plurality of data lines configured to supply data signals to the plurality of subpixels,
wherein the plurality of data lines are disposed to overlap the first area.

13. The display apparatus of claim 1, wherein
the plurality of subpixels include an organic light emitting layer in the light emission area and the non-light emission area,
wherein a refracted light corresponds to a light emitted from the organic light emitting layer that is incident on any one of the plurality of concave portions at a first angle from a direction perpendicular to the lower surface of the pixel electrode, and is refracted by at least one concave portion to reach the reflective portion,
an intensity of the refracted light I(θₘₐₓ) is provided to satisfy a following expression:
I(θₘₐₓ)=∫₀^{Φ}^{₀}I₀T_{P}(θₘₐₓ,Φ)dΦ
wherein Φ₀ is a maximum angle at which light incident at the first angle is transmitted to a side surface of the concave portion without being totally reflected in an interior of the concave portion, I₀ is an intensity of light incident on the concave portion, and T_{P} is a light transmittance at a point on the concave portion, θₘₐₓ is the first angle, Φ is a second angle between a virtual line VL and the upper surface of the concave portion, where the virtual line VL connects a center of the concave portion and the point of the concave portion through which light incident on the concave portion is transmitted.

14. The display apparatus of claim 13, wherein
the plurality of subpixels are disposed on the substrate and include an overcoat layer including a first layer including the plurality of concave portions and a second layer on the first layer,
the maximum angle Φ₀ is provided to satisfy a following expression:
$${Φ}_{0} = a tan ( - AR / tan ( {θ}_{max} - a sin ( N ) ) )$$
wherein AR is an aspect ratio of one concave portion of the plurality of concave portions, θₘₐₓ is the first angle, and N is a ratio of a refractive index of the first layer with respect to a refractive index of the second layer.

15. The display apparatus of claim 13, wherein
the light transmittance T_{P} of the point of the concave portion is provided to satisfy a following expression:
$${T}_{P} = 1 - ( {\vert \frac{sin {θ}_{1} - N sin {θ}_{2}}{sin {θ}_{1} + N sin {θ}_{2}} \vert}^{2} + {\vert \frac{N sin {θ}_{1} - sin {θ}_{2}}{N sin {θ}_{1} + sin {θ}_{2}} \vert}^{2} )$$
wherein θ₁ is an angle of incidence of light incident on the concave portion, θ₂ is a refractive index of light transmitting through the concave portion, and N is a ratio of the refractive index of the first layer with respect to the refractive index of the second layer.

16. The display apparatus of claim 15, wherein
the angle of incidence θ₁ is an angle between a normal to a tangent of the point of the concave portion and the light incident into the concave portion,
the angle of incidence θ₁ is provided to satisfy a following expression:
$${θ}_{1} = π / 2 - m - {θ}_{max}$$
wherein π is a constant, and m is a slope of the tangent of the point of the concave portion.

17. The display apparatus of claim 16, wherein
the angle of refraction θ₂ is an angle between the light transmitting through the concave portion and the normal,
the angle of refraction θ₂ is provided to satisfy a following expression:
θ₂=a sin(N sin(θ₁)).

18. The display apparatus of claim 16, wherein
the slope m is provided to satisfy a following expression:
$$m = \vert atan ( - \frac{cos Φ}{sin Φ} AR ) \vert$$
wherein AR is an aspect ratio of one concave portion of the plurality of concave portions.

19. The display apparatus of claim 14, wherein the first angle is a maximum angle at which light emitted by the organic light emitting layer passes through the pixel electrode to be incident on the second layer.

20. The display apparatus of claim 14, wherein when the aspect ratio of the concave portion is greater than or equal to 1.0, the intensity of the refracted light is greater than or equal to about 90% of the maximum intensity of the refracted light.

21. The display apparatus of claim 1, further comprising a plurality of data lines configured to supply data signals to the plurality of subpixels,
wherein the plurality of data lines are disposed to be extended in a second direction intersecting a first direction between the plurality of subpixels disposed in the first direction, and
the pattern portion partially overlaps the plurality of data lines in the first direction and the second direction.

22. The display apparatus of claim 1, wherein
the plurality of subpixels include a first subpixel, a second subpixel, a third subpixel, and a fourth subpixel disposed sequentially in a first direction,
the substrate includes a reference line extended in a second direction intersecting the first direction between the second subpixel and the third subpixel, and
at least a portion of the reference line overlaps the pattern portion.

23. The display apparatus of claim 1, wherein the pattern portion is disposed along a shape of the pixel electrode.

24. The display apparatus of claim 1, further comprising:
a plurality of thin film transistors to drive the plurality of subpixels,
wherein the substrate includes a connecting area in which the plurality of thin film transistors and the pixel electrode are connected, and
the pattern portion is not disposed in the connecting area.

25. The display apparatus of claim 1, further comprising a plurality of data lines configured to supply data signals to the plurality of subpixels,
wherein the plurality of data lines are disposed to extend in a second direction intersecting a first direction between the plurality of subpixels disposed in the first direction,
the pattern portion includes a first pattern line extended in the first direction and a second pattern line extended in the second direction, and
the second pattern line does not overlap the data line in the second direction.

26. The display apparatus of claim 25, the first pattern line is disposed between the subpixels for emitting light of the same color, and the second pattern line is disposed between the subpixels for emitting light of different colors.
